(19) United States
(12) Patent Application Publication
(10) Pub. No.: US 2006/0273355 A1
(43) Pub. Date: Dec. 7, 2006

(54) CMOS image sensor and method for manufacturing the same

(75) Inventor: Chang Hun Han, Icheon-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/447,423

(22) Filed: Jun. 5, 2006

(30) Foreign Application Priority Data
Jun. 7, 2005 (KR) 10-2005-0048483

(51) Int. Cl. H01L 29/768; H01L 21/00

(52) U.S. Cl. 257/239; 257/291; 257/292; 438/48; 257/E27.133

(57) ABSTRACT

A CMOS image sensor and manufacturing method thereof are disclosed. The present CMOS image sensor comprises: a first conductivity type semiconductor substrate having an isolation region and an active region, the active region including a blue (or cyan) photo diode region and a transistor region; an isolation layer in the isolation region of the semiconductor substrate; a first diffusion region having a conductivity type identical to the semiconductor substrate, in the blue photo diode region on one side of the isolation layer; a gate insulating layer and a gate electrode on the transistor region; and a second diffusion region having a conductivity type opposite to the semiconductor substrate, in the blue photo diode region such that the first diffusion region is between the second diffusion region and the isolation layer.

This application claims the benefit of Korean Patent Application No. 10-2005-0048483, filed on Jun. 7, 2005, which is incorporated by reference herein in its entirety.

### BACKGROUND OF THE INVENTION

1. Field of the Invention

The present invention relates to an image sensor, more specifically, to a complementary metal oxide semiconductor (CMOS) image sensor and manufacturing method thereof.

2. Description of the Related Art

An image sensor, as a kind of semiconductor device, transforms optical image into electrical signal, which can be generally classified into a charge coupled device (CCD) and a CMOS image sensor.

Conventionally, a CCD comprises a plurality of photo diodes arranged in the form of matrix to transform optical signal into electrical signal, a plurality of vertical charge coupled devices (VCCDs) formed between the photo diodes to transmit charges generating in each photo diode in a vertical direction, a plurality of horizontal charge coupled devices (HCCDs) for transmitting charges transmitted from each VCCDs in a horizontal direction, and a sense amp for sensing charges transmitted in the horizontal direction to output electrical signals.

It has been generally known that CCDs have complicated operational mechanism, and high power consumption. In addition, its manufacturing method is very complicated, because multiple steps of photolithography processes are required in its fabrication. Especially, it is difficult to integrate a CCD with other devices such as control circuits, signal processing circuits, analog/digital converter, etc., in a single chip. Such disadvantages of CCDs may hinder miniaturization of products containing a CCD.

In order to overcome above described disadvantages of CCDs, CMOS image sensors have been recently developed in the oncoming generation(s) of image sensors. CMOS image sensor comprises MOS transistors formed in a semiconductor substrate by CMOS fabrication technologies. In CMOS image sensor, the MOS transistors are formed relative to the number of unit pixels, along with peripheral circuits such as control circuits, signal processing circuits, and the like. CMOS image sensor employs a switching mode that MOS transistors successively detect the output of each pixel.

More specifically, a conventional CMOS image sensor may comprise a photo diode and MOS transistors in each pixel, thereby successively detecting electrical signals of each pixel in a switching mode to express a given image.

CMOS image sensors have advantages such as low power consumption and relatively simple fabrication process. In addition, CMOS image sensors can be integrated with control circuits, signal processing circuits, analog/digital converter(s), etc., because such circuits can be manufacturing using CMOS manufacturing technologies, which enables miniaturization of products.

CMOS image sensors have been widely used in a variety of applications such as digital still cameras, digital video cameras, and the like.

Meanwhile, CMOS image sensors can be classified into 3T, 4T, 5T types, etc., according to the number of transistors in a unit pixel. The 3T type CMOS image sensor comprises one photo diode and three transistors, and the 4T type comprises one photo diode and four transistors. Here, a unit pixel layout of the 3T type CMOS image sensor is configured as follows.

FIG. 1 shows a layout illustrating unit pixel in a conventional 3T type CMOS image sensor, and FIG. 2 shows a cross-sectional view illustrating a photo diode and a reset transistor of a conventional CMOS image sensor, in view of A-A′ line in FIG. 1.

As shown in FIG. 1, one photo diode region 20 is formed in a large portion of a defined active region, and three transistors 30, 40, and 50 are respectively formed to be overlapped in other portion 10 of the active region.

The transistor 30 constitutes a reset transistor, and the transistor 40 constitutes a driver transistor, and the transistor 50 constitutes a select transistor.

Here, dopant ions are implanted in the transistor region 10 of the active region where each transistor is formed, except the portion of active region 10 below each gate electrodes 30, 40, and 50, to form source and drain regions of each transistor.

Especially, a supply voltage (VDD) is applied to source/drain regions between the reset transistor and the driver transistor, and the source/drain regions formed at one side of the select transistor is connected to detecting circuits (not shown).

Transistors 30, 40, and 50 are respectively connected to signal lines, even though they are not illustrated in FIG. 1. In addition, signal lines are respectively connected to external driving circuits via additional pads respectively formed at one end thereof.

Referring to FIG. 2, P− type epitaxial layer 12 is formed on a P++ type semiconductor substrate 11. In addition, the semiconductor substrate 11 including the epitaxial layer 12 is defined by the active region including the photo diode region 20 and, the transistor region 10, as shown in FIG. 1, and an isolation region where isolation layer 13 is formed.

As shown in FIG. 2, gate electrode 15 for the reset transistor 30 is formed on epitaxial layer 12, interposing gate insulating layer 14. A pair of insulating sidewalls 16 is formed on both sides of gate electrode 15.

In addition, a N− type diffusion region 20 is formed in photo diode region of epitaxial layer 12. Lightly doped drain (LDD) region 17 and source/drain diffusion regions 18 are respectively formed in the transistor region of epitaxial layer 12. A P0 type diffusion region 21 is formed over the N− type diffusion region 20 in the photo diode region.

In the above-described structure of CMOS image sensor, a reverse bias is applied between the N− type diffusion region 20 and the P− type epitaxial layer 12, thus resulting in a depletion layer where electrons are generated by a light. When the reset transistor turns off, the generated electrons lower the potential of the driver transistor. Lowering of potential of the driver transistor proceeds continuously from turn-off of the reset transistor, thus resulting in potential difference. The image sensor can be operated by detecting the potential difference as a signal.

On the other hand, photo diodes are arranged according to the fixed structure of pixel array. Namely, the pixel array is configured in Bayer patterns in which a first line of GBGB pattern and a second line of RGRG pattern are arranged by turns, as shown in FIG. 3.

Referring to FIG. 3, green (G), red (R), and blue (B) pixels are formed in the identical structure, but each pixel has different color reproducibility on a light.

Problems on the color reproducibility of CMOS image sensor are caused by wave properties of a light. Generating rate of electron and hole pair (EHP) by a light depends on a wavelength of light, as shown in FIG. 4.

FIG. 5 is a graph illustrating changes of absorption coefficient and penetration depth according to the wavelength of light.

Referring to FIG. 5, red light penetrates up to 10 μm below a surface of silicon substrate. However, blue light penetrates just to 0.3 μm (i.e., 3000 Å) below a surface of silicon substrate, which represents a poor color reproducibility of blue light.

The color reproducibility of blue light can be evaluated by B/G ratio. Especially, the specification of B/G ratio required in a commercial product is in a range of from 0.6 to 1.0. The upper limit of 1.0 is just an ideal value, but the lower limit of 0.6 is the very important standard.

In order to improve sensitivity of blue signal, a blue filter process (or, in a YCM [yellow-cyan-magenta] system, a cyan filter) is generally performed before a green filter process, however, which may induce another problem. Specifically, a conventional CMOS image sensor employs Bayer pattern that comprises one blue (or cyan) pixel per four pixels, and peeling phenomenon of blue pixel frequently occurs after its formation process.

Typically, in order to improve adhesive strength of pixel, additional photolithography processes are necessarily performed before color filter process. As a result, the distance from a surface of silicon substrate to color filters becomes increased so that total color reproducibility becomes more deteriorated.

### SUMMARY OF THE INVENTION

It is, therefore, an object of the present invention to provide a CMOS image sensor, wherein the sensitivity to a blue (or cyan) light and total color reproducibility of the image sensor are improved.

Another object of the present invention is to provide a method for manufacturing a CMOS image sensor in which the sensitivity to a blue (or cyan) light and total color reproducibility of the image sensor are improved.

To achieve the above objects, an embodiment of a CMOS image sensor according to the present invention comprises: a first conductivity type semiconductor substrate having an isolation region and an active region, the active region including a blue (or cyan) photo diode region and a transistor region; an isolation layer formed in the isolation region of the semiconductor substrate; a first diffusion region having a conductivity type identical to the semiconductor substrate, formed in the blue (or cyan) photo diode region on (e.g., close to) one side of the isolation layer; a gate insulating layer and a gate electrode formed on the substrate in the transistor region; and a second diffusion region having a conductivity type opposite to the semiconductor substrate, formed in the blue (or cyan) photo diode region relatively distant from the isolation layer, wherein the first diffusion region (at least part) is between the second diffusion region and the isolation layer.

In a CMOS image sensor according to the present invention, the first diffusion region can have a diffusion depth equal to or greater than that of the second diffusion region. In addition, a third diffusion region can be formed over or in the second diffusion region in the blue photo diode region, wherein the third diffusion region has a conductivity type identical to the semiconductor substrate. Preferably, the first diffusion region has a higher dopant concentration than that of the third diffusion region.

In addition, a method for manufacturing a CMOS image sensor according to the present invention comprises the steps of: defining an isolation region and an active region in a first conductivity type semiconductor substrate, the active region including a blue (or cyan) photo diode region and a transistor region; forming a sacrificial insulating layer on the semiconductor substrate; removing a portion of the sacrificial insulating layer selectively to expose (at least part of) the isolation region of the substrate; etching an exposed portion of the substrate to form a trench in the isolation region; tilt-implanting a first conductivity type dopant at a predetermined angle using the sacrificial insulating layer as a mask, thus forming a first diffusion region in the blue (or cyan) photo diode region on (e.g., close to or immediately adjacent) one side of the trench; filling the trench with an insulating material to form an isolation layer; removing a remaining portion of the sacrificial insulating layer; forming a gate insulating layer and a gate electrode on the transistor region; forming a second diffusion region in the blue (or cyan) photo diode region relatively distant from the isolation layer, the second diffusion having a conductivity type opposite to the semiconductor substrate, wherein the first diffusion region (at least part) is between the second diffusion region and the isolation layer.

A manufacturing method of a CMOS image sensor according to the present invention can further comprise the step of forming a thermal oxidation layer on inner walls of the trench after forming the trench (e.g., thermally oxidizing the substrate exposed in the trench). In addition, the first diffusion region can be formed by implanting boron (B) or BF₂ ions. Especially, the first diffusion region can be formed by implanting B ions at an ion implantation energy of from 15 keV to 50 keV, or implanting BF₂ ions at an ion implantation energy of from 20 keV to 60 keV. Preferably, the implantation for the first diffusion region is performed at a dopant dose of from 1.0E12 to 4.0E13. In addition, the second diffusion region can be formed by implanting phosphorus (P) ions at an ion implantation energy of from 150 keV to 300 keV.

A manufacturing method of a CMOS image sensor according to the present invention can further comprise the step of forming a third diffusion region over or in the second diffusion region in the blue (or cyan) photo diode region, wherein the third diffusion region has a conductivity type identical to the semiconductor substrate. Preferably, the first diffusion region has a higher dopant concentration than that of the third diffusion region.

These and other aspects of the invention will become evident by reference to the following description of the invention, often referring to the accompanying drawings.

### BRIEF DESCRIPTION OF DRAWINGS

FIG. 1 is a layout of unit pixel of a conventional 3T type CMOS image sensor.

FIG. 2 is a cross-sectional view illustrating a photo diode and a reset transistor of the conventional CMOS image sensor, in a view of A-A′ line in FIG. 1.

FIG. 3 shows a pixel array of Bayer pattern, in which a first line in GBGB pattern and a second line in RGRG pattern are arranged by turns, in the conventional CMOS image sensor.

FIG. 4 is a graph illustrating variation of the generating rate of electron and hole pair (EHP) by a light depending on a wavelength of light.

FIG. 5 is a graph illustrating changes of absorption coefficient and penetration depth according to the wavelength of light.

FIG. 6 is a layout of unit pixel in a CMOS image sensor according to the present invention.

FIG. 7 is a cross-sectional view illustrating a photo diode and a reset transistor of the CMOS image sensor according to the present invention, in a view of II-II′ line in FIG. 6.

FIGS. 8a to 8l are cross-sectional views illustrating an embodiment of a method for manufacturing a CMOS image sensor according to the present invention, in a view of II-II′ line in FIG. 6.

FIGS. 9 and 10 are graphs illustrating results of experiments on a CMOS image sensor according to the present invention.

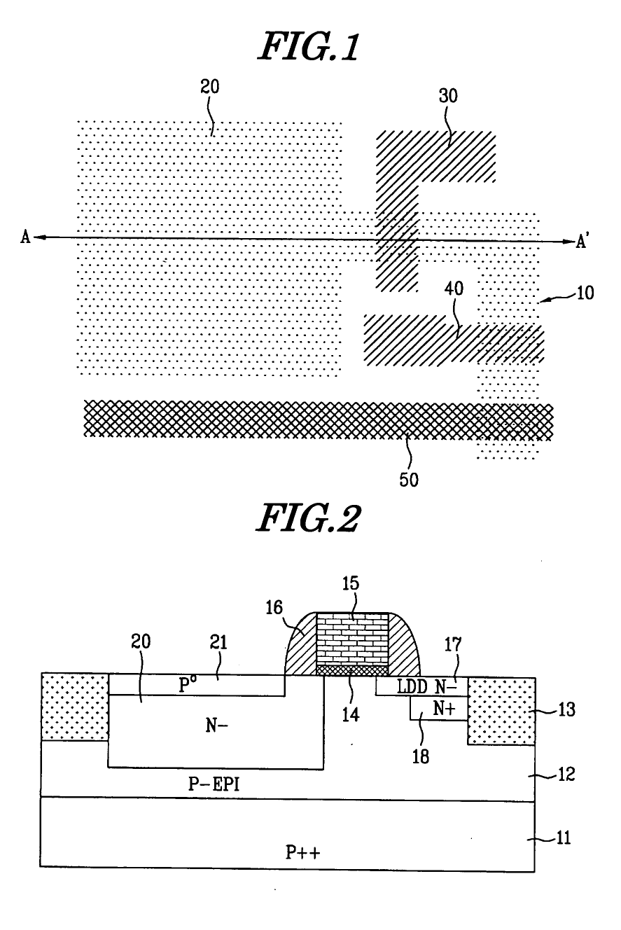

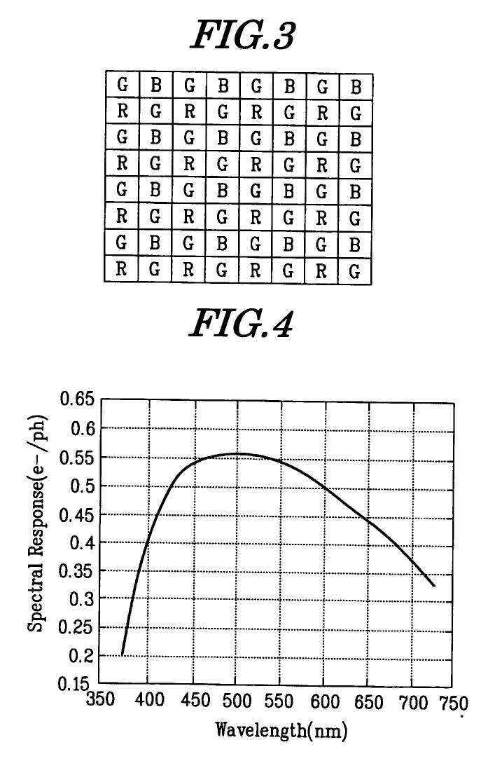

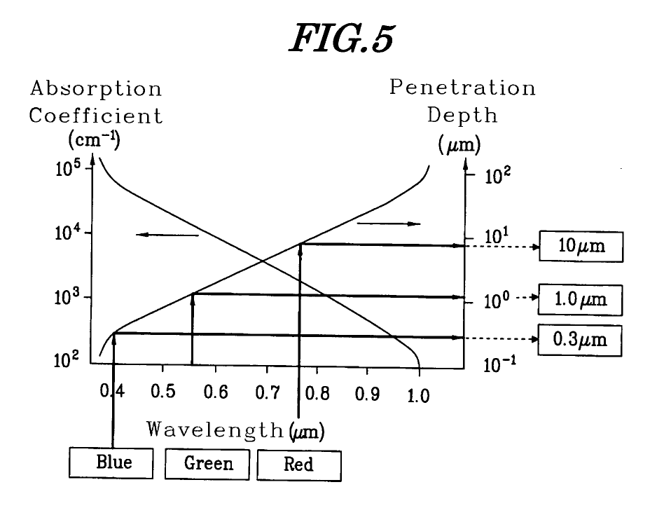

### DETAILED DESCRIPTION OF THE INVENTION

Hereinafter, for convenience of explanation, the preferred embodiment of CMOS image sensor, according to the present invention, will be described based on 3T CMOS image sensor having one photo diode and three transistors in unit cell. However, the present invention is not limited to the 3T structure, but it may be configured in a 4T structure consisting of one photo diode and four transistors (i.e., a reset transistor, transfer transistor, driver transistor, and select transistor) or a 5T structure.

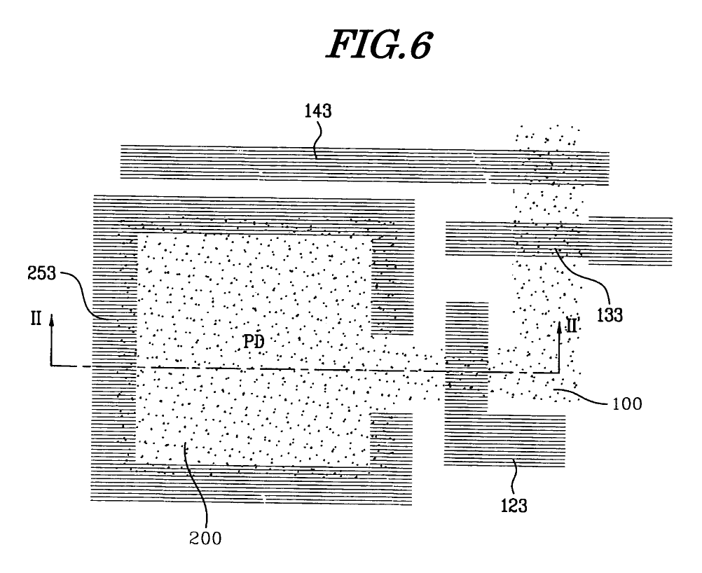

FIG. 6 is a layout illustrating unit pixel of a CMOS image sensor according to the present invention.

As shown in FIG. 6, in unit pixel of CMOS image sensor according to the present invention, an active region is defined in one portion of semiconductor substrate, and an isolation region is defined in other portion of semiconductor substrate. Isolation layer is formed in the isolation region of the substrate. One photo diode (PD) is formed in the large portion of the active region (i.e., photo diode region 200), and three transistor gates 123, 133, and 143 are formed to be overlapped in other portion of the active region (i.e., transistor region 100). The gate electrode 123 constitutes a reset transistor, the gate electrode 133 constitutes a driver transistor, and the gate electrode 143 constitutes a select transistor.

Here, dopant ions are implanted in transistor region 100 where transistors are formed, except portions of active region below each gate electrodes 123, 133, and 143, thus forming source and drain regions of each transistor.

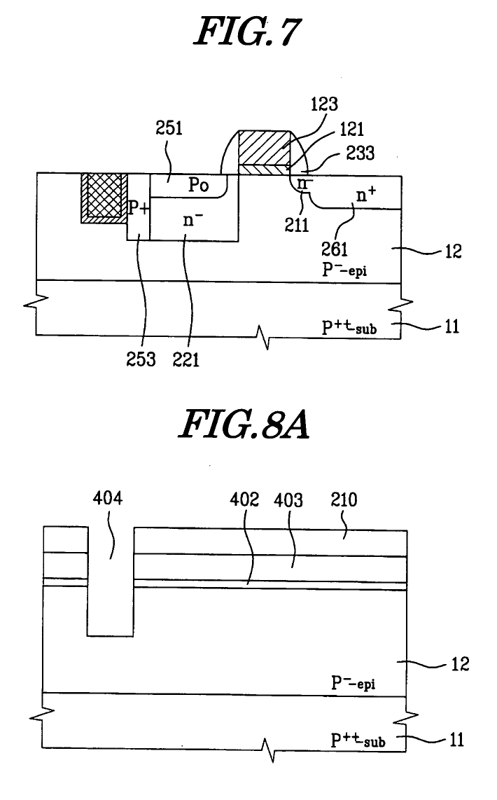

FIG. 7 is a cross-sectional view illustrating a photo diode and a reset transistor of a CMOS image sensor according to the invention, in view of II-II′ line in FIG. 6.

As shown in FIG. 7, a P− type epitaxial layer 12 is formed on a P++ type semiconductor substrate 11. A single crystalline silicon substrate can be used as the semiconductor substrate 11.

In addition, the semiconductor substrate 11 is defined by an active region including the photo diode region 200 and transistor region 100, as shown in FIG. 6, and an isolation region where isolation layer 13 is formed. Isolation layer 13 can be formed by shallow trench isolation (STI) process or local oxidation of silicon (LOCOS) process.

Gate electrode 123 for the reset transistor is formed on epitaxial layer 12 of the transistor active region, interposing the gate insulating layer 123. A pair of insulating sidewalls 233 is formed on both sides of gate electrode 123.

In addition, a N− type diffusion region 221 and a P0 type diffusion region 251 are formed in the photo diode region of epitaxial layer 12. The P0 type diffusion region 251 is formed over the N− type diffusion region 221 at a predetermined distance from the gate electrode 123.

A source/drain region, including a N− type lightly doped region 211 and a N+ type heavy doped region 261, is formed in the transistor region of epitaxial layer 12.

A P+ type diffusion region 253 is formed in epitaxial layer 12 between the isolation layer 13 and the N− type diffusion 221 (and the P0 type diffusion region 251). Preferably, the P+ type diffusion region 253 is formed in a diffusion depth equal to or greater than that of the N− type diffusion region 221.

On the other hand, in the present embodiment, the photo diode preferably has the N− type diffusion region 221 and the P0 type diffusion region 251, but the present invention can employs only the N− type diffusion region 221 for the photo diode.

Here, “P−” type diffusion region indicates a doped region having a (relatively) low concentration of P-type dopants, a “P0” type diffusion region indicates a doped region having a middle or (relatively) medium concentration of P-type dopants, and a “P+” type diffusion region indicates a doped region having a (relatively) high concentration of P-type dopants, and finally a “P++” type diffusion region indicates a doped region having a (relatively) very high concentration of P-type dopants. Similarly, “N−” type diffusion region indicates a doped region having a (relatively) low concentration of N-type dopants, and a “N+” type diffusion region indicates a doped region having a (relatively) high concentration of N-type dopants.

In the above-described structure of CMOS image sensor, the N− type diffusion region 221 and the P0 type diffusion region 251, constituting the photo diode, are arranged distant from the isolation layer 12, because of the P+ type diffusion region 253. Thus, it prevents or reduces occurrence of dark currents at interfaces between the isolation layer 13 and the N− type diffusion region 221 (and/or the P0 type diffusion region 251). Specifically, EHPs may occur in the interface between the isolation layer 13 and the photo diode region, but they are rejoined in the P+ type diffusion region 253. Accordingly, the occurrence of dark currents at the interface can be prevented or reduced.

Moreover, if the P0 type diffusion region 251 is extended below the gate electrode 123, a barrier potential can be induced in the portion of the photo diode region adjacent to the gate electrode 123, thereby resulting in reduction of charge transfer efficiency from the photo diode region to the source/drain region. However, in the preferred embodiment to the present invention, the P0 type diffusion region 251 is formed at a predetermined distance from the gate electrode 123, thus enabling improvement of charge transfer efficiency.

Especially, the photo diode region is preferably formed to be a blue (or cyan) photo diode region. In this case, because the P+ type diffusion region 253 is formed between the isolation layer 13 and the N− type diffusion region 221, the sensitivity of blue light can be more improved and the total color reproducibility of CMOS image sensor can be improved.

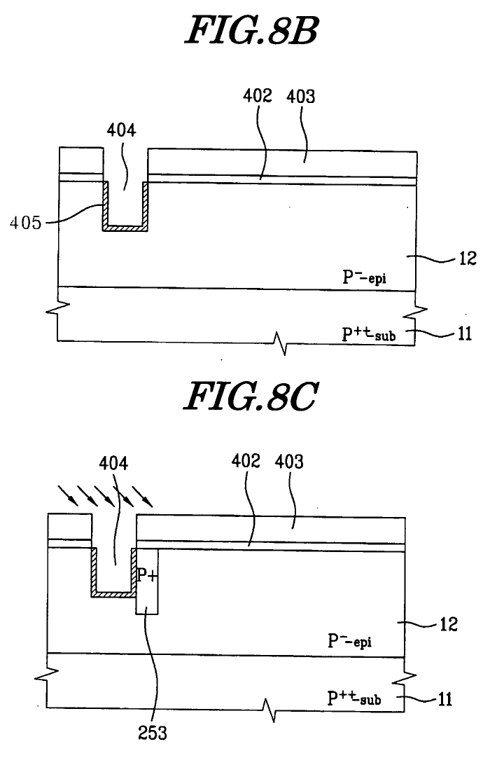

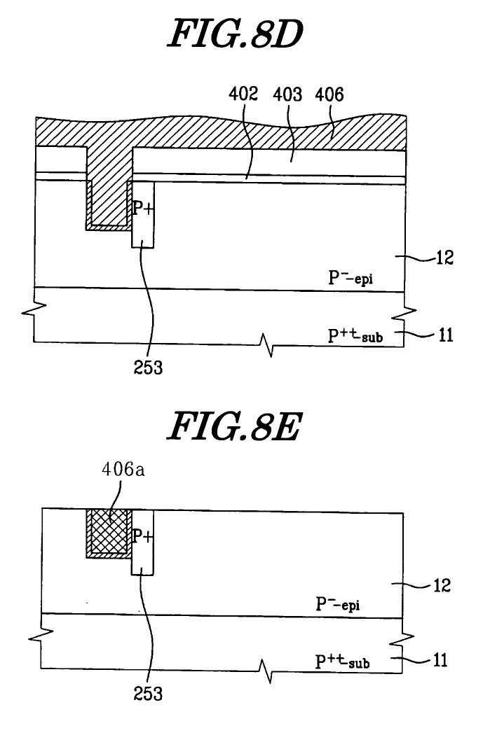

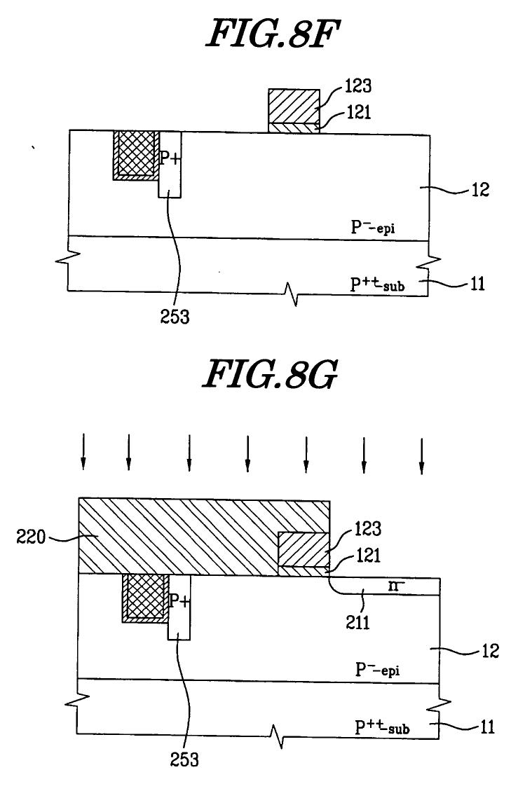

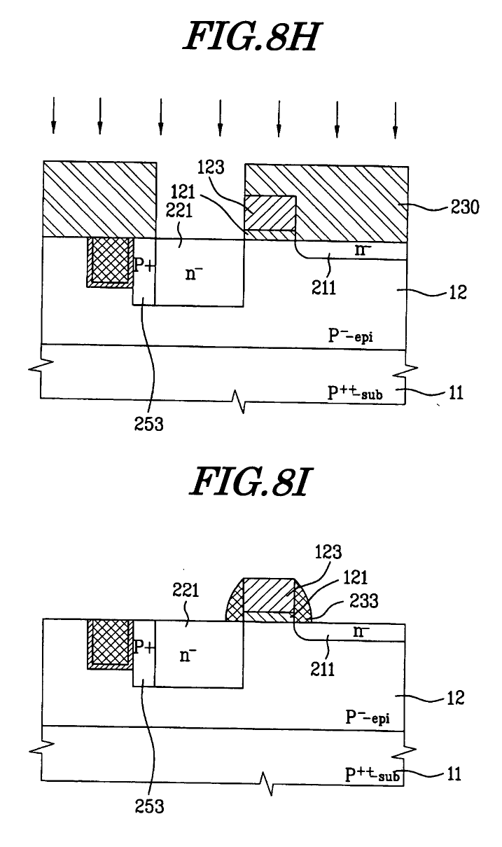

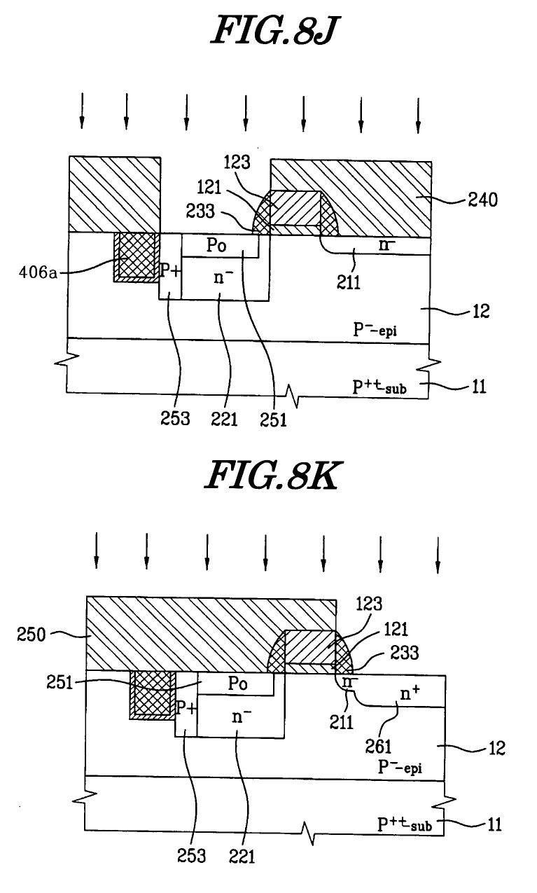

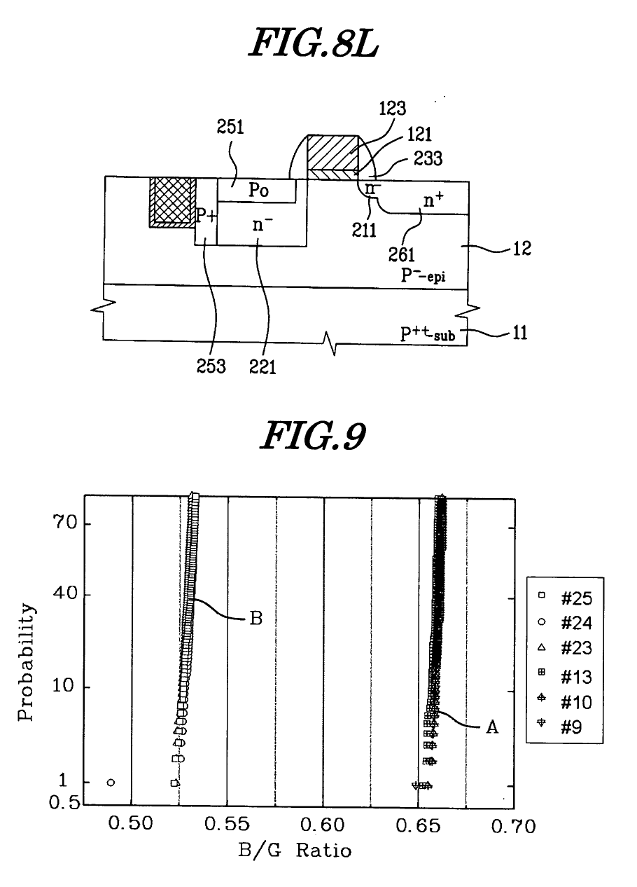

FIGS. 8a to 8l are cross-sectional views illustrating an embodiment of a method for manufacturing a CMOS image sensor according to the present invention, in a view of II-II′ line in FIG. 6.

Referring to FIG. 8a, a P− type epitaxial layer 12 is formed on the semiconductor substrate 11 such as single crystalline silicon having a heavy concentration and a first conductivity type (e.g., P++ type).

Here, the epitaxial layer 11 functions to form a deep and wide depletion region in the photo diode region. Thereby, the ability of a low voltage photo diode for gathering photoelectrons can be improved, and also the light sensitivity can be improved.

Next, a sacrificial oxide 402 is formed in a thickness of 40˜150 Å on an entire surface of the epitaxial layer 12, using high-temperature thermal oxidation.

Continuously, a sacrificial nitride 403 is formed in a thickness of 500˜1500 Å on the sacrificial oxide 402, using low-pressure chemical vapor deposition (LPCVD).

The sacrificial oxide 402 functions to reduce stresses of the epitaxial layer 12 due to the sacrificial nitride 403. The sacrificial nitride 403 is used as an etch mask during the subsequent process for forming a trench, and a barrier during the subsequent chemical mechanical polishing (CMP).

Subsequently, a photoresist layer 210 is applied on the sacrificial nitride 403, and then it is patterned in exposure and development processes to expose a portion of the sacrificial nitride 403 in the isolation region.

Using the patterned photoresist layer 210 as an etch mask, the sacrificial nitride 403 and the sacrificial oxide 402 are selectively removed to expose a portion of the epitaxial layer 12 in the isolation region.

Then, using the sacrificial nitride 403 as an etch mask, the epitaxial layer 12 is selectively removed in a predetermined depth to form a trench 404 in the isolation region.

As shown in FIG. 8b, after removal of the patterned photoresist layer 210, a thermal oxidation layer 405 is formed in a thickness of 200˜400 Å on inner walls of the trench 404, by thermal oxidation process using the sacrificial nitride 403 as a mask.

Here, the thermal oxidation layer 405 functions to cure damages of the surface of the epitaxial layer inside the trench 404 by plasma during formation of the trench 404, more specifically, to remove dangling bonds existing in silicon lattices in the vicinity of the surface of the epitaxial layer 12 exposed by the trench 404.

In addition, the thermal oxidation layer 405 serves to improve adhesive strength of an isolation layer to be formed in the subsequent process. Yet, in the present invention, the thermal oxidation layer 405 is not an indispensable component.

Next, as shown in FIG. 8c, a high concentration of first conductivity type dopant ions are implanted at tilt on one side of the trench 404 where the thermal oxidation layer 405 is formed, thus forming the P+ type diffusion region 253.

Especially, the P+ type diffusion region 253 is preferably formed by implanting boron (B) or BF₂. In the case of using boron, an ion implantation energy is preferably 15 keV˜50 keV. In the case of using BF₂, an ion implantation energy is preferably 20 keV˜60 keV. In addition, a dopant dose implanted in the P+ type diffusion region is preferably from 1.0E12˜4.0E13.

More preferably, the ion implantation for the P+ type diffusion region 253 is performed under conditions comprising a dopant dose of 1.0E12, an ion implantation energy of 30 keV, with quarterly tilting an implanting angle. In addition, the ion implantation process can be performed on one side of the trench 404 which can be divided into four sections.

As shown in FIG. 8d, an insulating material 406 for the isolation layer is deposited over the entire surface of the semiconductor substrate, filling the trench 404 sufficiently, and preferably without voids therein.

Preferably, the insulating material 406 is deposited by APCVD (Atmosphere Pressure Chemical Vapor Deposition) process using O₃-TEOS (Tetra-Ethyl-Ortho-Silicate), or HDPCVD (high density plasma chemical vapor deposition) process.

As shown in FIG. 8e, the insulating layer 406 is planarized by CMP process to expose the surface of the sacrificial nitride 403.

Subsequently, the sacrificial nitride 403 is removed by a wet etch process using phosphoric acid, thus forming the isolation layer 406a. The sacrificial oxide 402 can be removed during removal of the sacrificial nitride 403.

Referring to FIG. 8f, an insulating layer and a conductivity layer are deposited on the entire surface of the substrate, in successive order, and these layers are patterned by photolithography and etch processes, thus forming the gate insulating layer 121 and the gate electrode 123.

Next, as shown in FIG. 8g, a photoresist layer is applied over the entire surface of the substrate including the gate electrode 123, and then it is patterned by exposure and development processes, thus forming the photoresist pattern 220 which covers the photo diode region and exposes the transistor region where source/drain regions will be formed.

Using the photoresist pattern 220 as a mask, a low concentration of N-type dopant ions are implanted in the exposed transistor region to form the N− type diffusion region 211.

As shown in FIG. 8h, after removal of the photoresist pattern 220, another photoresist layer is applied over the substrate, and then it is patterned by exposure and development processes, thus forming the photoresist pattern 230 which expose the photo diode region.

Then, using the photoresist pattern 230 as a mask, a low concentration of N− type dopant ions are implanted in the photo diode region to form the N− type diffusion region 221.

Especially, phosphorus (P) can be used as the dopant ion for the N− type diffusion region 221, and it may be implanted under conditions comprising an ion implantation energy of 150 keV˜300 keV, and a dopant dose of about 6.0E12.

Meanwhile, the N− type diffusion region 221 in the photo diode region is preferably formed in a depth greater than that of the N− type diffusion region 211 of source/drain regions.

As shown in FIG. 8i, after removing the photoresist pattern 230, an insulating layer, such as oxide or nitride, etc., is formed over the entire surface of the substrate by CVD, e.g., a LPCVD (Low Pressure Chemical Vapor Deposition) process.

Continuously, an etch back process (e.g., comprising anisotropic etching) is performed on the insulating layer to form insulating sidewalls 233 (which, in cross-section, appears as a pair of sidewall spacers) on both sides of the gate electrode 123.

As shown in FIG. 8j, a photoresist layer is applied over the substrate, and then it is patterned by exposure and development processes to form the photoresist pattern 240 exposing the photo diode region.

Then, using the photoresist pattern 240 as a mask, a middle concentration of P-type dopant ions are implanted in the photo diode region to form the P0 type diffusion region 251 over the N− type diffusion region 221.

At this time, the P0 type diffusion region 251 is formed distant from the isolation layer 406a and the gate electrode 123, respectively. Especially, because the insulating sidewalls 233 are formed on both sides of the gate electrode 123, the P-type dopant ions are not implanted in the portion of the photo diode region below the insulating sidewall 233.

Here, the photo diode can comprise or consist essentially of the N− type diffusion region 221, without the P0 type diffusion region 251.

As shown in FIG. 8k, after removing the photoresist pattern 240, a photoresist layer is formed over the entire surface of the substrate, and then it is patterned by exposure and development processes to form the photoresist pattern 250 which covers the photo diode region and exposes the transistor region.

Continuously, using the photoresist pattern 250 as a mask, a high concentration of N-type dopant ions are implanted in source/drain regions to form the N+ type diffusion region 261.

As shown in FIG. 8l, after removing the photoresist pattern 250, a heat-treatment process, e.g., a rapid thermal (annealing) process, is performed on the substrate to activate dopants in the N− type diffusion region 221, the P0 type diffusion region 251, the P+ type diffusion region 253, the N− type diffusion region 211, and the N+ type diffusion region 261.

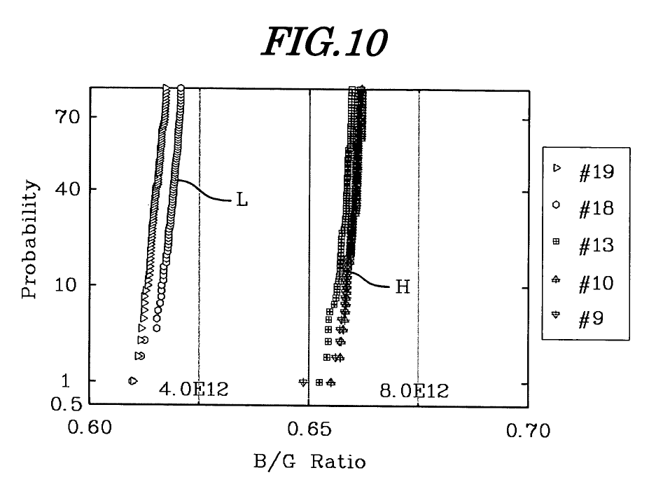

FIGS. 9 and 10 are graphs illustrating results of experiments on a CMOS image sensor according to the present invention.

In the CMOS image sensor used in experiments, the P+ type diffusion region 253 is formed under conditions comprising a boron or BF₂ dopant (or ion), a dopant dose of 1.0E12, an ion implantation energy of 30 keV, and quarterly tilt-implanting steps. In addition, the N− type diffusion region 221 is formed under conditions comprising a phosphorus dopant (or ion), an ion implantation energy of 230 keV, and a dopant dose of 6.0E12.

The experimental results, as shown in FIG. 9, illustrate that B/G ratio is conspicuously improved in the case of the present invention. More specifically, referring to FIG. 9, the B/G ratio (referred to as “A”) of the CMOS image sensor according to the present invention has a higher value than that of a conventional CMOS image sensor (referred to as “B”) by about 25%. In addition, the B/G ratio can be changed according to a dopant dose implanted in the P+ type diffusion region 253. FIG. 10 shows that the B/G ratio in the case of a dopant dose of 8.0E12 (referred to as “H”) has a higher value than that of in the case of a dopant dose of 4.0E12 (referred to as “L”) by about 6%.

According to the present invention, implantation energies in ion implantation processes for a blue photo diode region where blue color light is absorbed are optimized, and a high concentration of P-type diffusion region is formed between the isolation layer and the blue photo diode region, thus enabling improvement of the sensitivity on a blue light and the total color reproducibility of a CMOS image sensor. Similar results are expected for a cyan photodiode in a YCM CMOS image sensor.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A CMOS image sensor, comprising:
a semiconductor substrate having a first conductivity type, an isolation region and an active region, the active region including a blue or cyan photo diode region and a transistor region;
an isolation layer in the isolation region;
a first diffusion region having the first conductivity type, in the blue or cyan photo diode region on one side of the isolation layer;
a gate insulating layer and a gate electrode in the transistor region; and
a second diffusion region having a second conductivity type, in the blue or cyan photo diode region such that the first diffusion region is between the second diffusion region and the isolation layer.

2. The CMOS image sensor of claim 1, wherein the first diffusion region has a depth equal to or greater than that of the second diffusion region.

3. The CMOS image sensor of claim 1, further comprising a third diffusion region formed over or in the second diffusion region in the blue or cyan photo diode region, wherein the third diffusion region has the first conductivity type.

4. The CMOS image sensor of claim 3, wherein the first diffusion region has a higher dopant concentration than that of the third diffusion region.

5. The CMOS image sensor of claim 1, wherein the first conductivity type is a P type, and the second conductivity type is an N type.

6. The CMOS image sensor of claim 5, wherein the semiconductor substrate has a P++ conductivity type, the first diffusion region has an N− type and the second diffusion region has a P+ conductivity type.

7. The CMOS image sensor of claim 6, further comprising a third diffusion region formed over or in the second diffusion region in the blue or cyan photo diode region, wherein the third diffusion region has a P0 conductivity type.

8. The CMOS image sensor of claim 1, further comprising a source/drain region having the second conductivity type in the transistor region on a side of the gate electrode opposite to the blue or cyan photo diode region.

9. A method for manufacturing a CMOS image sensor, comprising the steps of:
tilt-implanting a dopant having a first conductivity type at a predetermined angle into a substrate having a sacrificial layer thereon, an exposed trench in an isolation region and a blue or cyan photo diode region in an active region, using the sacrificial insulating layer as a mask, thus forming a first diffusion region in the blue or cyan photo diode region on one side of the trench;
filling the trench with an insulating material to form an isolation layer;
removing a remaining portion of the sacrificial insulating layer;
forming a gate insulating layer and a gate electrode on a transistor region of the substrate;
forming a second diffusion region in the blue or cyan photo diode region having a second conductivity type such that the first diffusion region is between the second diffusion region and the isolation layer.

10. The method of claim 9, further comprising the steps of:
removing a portion of the sacrificial insulating layer to expose the isolation region of the substrate; and
etching the exposed portion of the substrate to form the trench.

11. The method of claim 10, further comprising the step of forming a thermal oxidation layer on inner walls of the trench after forming the trench.

12. The method of claim 9, wherein forming the first diffusion region comprises implanting boron (B) or BF₂ ions.

13. The method of claim 12, wherein forming the first diffusion region comprises implanting B ions at an energy of from 15 keV to 50 keV.

14. The method of claim 12, wherein forming the first diffusion region comprises implanting BF₂ ions at an energy of from 20 keV to 60 keV.

15. The method of claim 9, wherein the tilt-implantation for the first diffusion region is performed at a dopant dose of from 1.0E12 to 4.0E13.

16. The method of claim 9, wherein forming the second diffusion region comprises implanting phosphorus (P) ions at an ion implantation energy of from 150 keV to 300 keV.

17. The method of claim 9, further comprising the step of forming a third diffusion region having the first conductivity type over or in the second diffusion region in the blue or cyan photo diode region.

18. The method of claim 17, wherein the first diffusion region has a higher dopant concentration than that of the third diffusion region.

19. The method of claim 9, further comprising the steps of:
defining an isolation region and an active region in the semiconductor substrate, the semiconductor substrate having the first conductivity type, and the active region including the blue or cyan photo diode region and a transistor region; and
forming the sacrificial insulating layer on the semiconductor substrate.

20. The method of claim 9, wherein the first conductivity type is a P type, and the second conductivity type is an N type.
